(19) United States
(12) Patent Application Publication
(10) Pub. No.: US 2025/0312871 A1
(43) Pub. Date: Oct. 9, 2025

(54) METHOD FOR MANUFACTURING SEMICONDUCTOR CHIP AND METHOD FOR DICING STACKED WAFER

(71) Applicant: CANON KABUSHIKI KAISHA, Tokyo (JP)

(72) Inventors: TETSURO YASUKAWA, Chiba (JP); TAKESHI SHIBATA, Kanagawa (JP)

(21) Appl. No.: 19/096,447

(22) Filed: Mar. 31, 2025

(30) Foreign Application Priority Data
Apr. 3, 2024 (JP) 2024-060092

(51) Int. Cl. B23K 26/53; B23K 26/38; B23K 101/40; H01L 21/67; H01L 21/78

(52) U.S. Cl. CPC B23K 26/53; B23K 26/38; H01L 21/67092; H01L 21/67132; H01L 21/78; B23K 2101/40

(57) ABSTRACT

A method for manufacturing a plurality of semiconductor chips from a stacked wafer in which a first wafer and a second wafer are joined with adhesive, and at least one of the first wafer and the second wafer includes an intermediate layer provided on a side joined to the adhesive. The method comprises dicing the stacked wafer along a cutting line with cracks generated in a modified region formed by irradiation of laser beam from the first wafer. The dicing includes irradiating laser beam along a region where the first wafer is removed along the cutting line with a laser beam.

### BACKGROUND

### Technical Field

The present disclosure relates to a method for manufacturing a semiconductor chip and a method for dicing a stacked wafer.

### Description of the Related Art

In recent years, in dicing processing of a semiconductor wafer, stealth dicing has been used as a method of dicing a wafer that can cleave a multilayered wafer with high accuracy.

In stealth dicing, laser beams are emitted and focused at a predetermined depth along a predetermined dicing line, forming a modified region with low crystal strength. When force is applied from the outside on the modified region as a starting point in, for example, expanding processing cracks extending in a thickness direction of the wafer are generated, enabling the wafer to be divided. As described above, stealth dicing is a method of cutting a wafer in a non-contact manner in dry processing, reducing damage and stain on the wafer.

Japanese Patent Application Laid-Open No. 2006-286727 discusses a stealth dicing method for a silicon on insulator (SOI) substrate as a wafer including a plurality of layers different in refraction index. In the method disclosed in Japanese Patent Application Laid-Open No. 2006-286727, among layers on a dicing line to be irradiated with a laser beam, the layer(s) (non-modified-region-forming layer(s)) other than a layer (modified-region-forming layer) that is positioned on the incident side of the laser beam to form the modified region is or are removed before an emission of the laser beam. This allows the laser beam to enter the wafer without reflecting or scattering from the non-modified-region-forming layer(s), and form the modified region. This allows appropriate cleavage to be performed using the modified region at an appropriate position.

Multilayered wafers include a stacked wafer where a plurality of substrates is joined with adhesion layers made of adhesive. For example, a chip used for a liquid ejection head of an inkjet printer has a stacked structure in which an ink flow path substrate, a substrate including ejection ports, a substrate including an actuator for ejecting liquid, and a substrate including a flow path of the ink are joined with adhesion layers. Many bonding interfaces of stacked chips have a multilayer structure that, in addition to an adhesive layer, includes a layer provided on a bonding surface of a substrate, the layer being used for maintaining adhesion and insulation of the wafer.

In stealth dicing of a stacked wafer to obtain the stacked chip, even when reflection and scattering of laser beams are prevented using the technique discussed in Japanese Patent Application Laid-Open No. 2006-286727, laser thermal impact generated during wafer modification can affect a bonding interface of the stacked wafer. This can cause stress due to the difference in liner expansion of a plurality of layers on the bonding interface, resulting in peeling of the wafer or substrate at the bonding interface.

### SUMMARY

The present disclosure is directed to a method for manufacturing a semiconductor chip and a method for dicing a stacked wafer that reduces peeling of a substrate at a bonding interface.

According to an aspect of the present disclosure, a method for manufacturing a plurality of semiconductor chips from a stacked wafer in which a first wafer and a second wafer are joined with adhesive, and at least one of the first wafer and the second wafer includes an intermediate layer provided on a side joined to the adhesive, the method comprising dicing the stacked wafer along a cutting line with cracks generated in a modified region formed by irradiation of laser beam from the first wafer, wherein the dicing includes irradiating along a region where the first wafer is removed along the cutting line with a laser beam.

According to another aspect of the present disclosure, a method for manufacturing semiconductor chips from a stacked wafer in which a first wafer and a second wafer is joined with adhesive, and at least one of the first wafer and the second wafer includes an intermediate layer provided on a side joined to the adhesive, the method comprising dicing the stacked wafer along a cutting line with cracks generated in a modified region formed by irradiation of laser beam from the first wafer, wherein the dicing includes irradiating laser beam along a region where the intermediate layer is removed along the cutting line with a laser beam.

Further features of the present disclosure will become apparent from the following description of exemplary embodiments with reference to the attached drawings.

### BRIEF DESCRIPTION OF THE DRAWINGS

FIG. 1 is a perspective view illustrating an example of a liquid ejection apparatus according to a first exemplary embodiment.

FIG. 2 is a perspective view illustrating an example of a liquid ejection head according to the first exemplary embodiment.

FIG. 3 is a perspective view illustrating a liquid ejection unit according to the first exemplary embodiment.

FIG. 4 is an exploded perspective view illustrating the liquid ejection unit according to the first exemplary embodiment.

FIG. 5 is a cross-sectional view illustrating an ejection chip according to the first exemplary embodiment.

FIG. 6 is a perspective view illustrating the ejection chip according to the first exemplary embodiment.

FIG. 7 is a flowchart of stealth dicing.

FIG. 8 is a perspective view illustrating a partial structure of a stacked wafer according to the first exemplary embodiment.

FIG. 9 is an enlarged cross-sectional view illustrating a layer structure of the stacked wafer according to the first exemplary embodiment.

FIG. 10 is an enlarged cross-sectional view illustrating a layer structure of a stacked wafer according to a second exemplary embodiment.

FIG. 11 is an enlarged cross-sectional view illustrating a layer structure of a stacked wafer according to a third exemplary embodiment.

FIG. 12 is an enlarged cross-sectional view illustrating a layer structure of a stacked wafer according to a modification of the third exemplary embodiment.

FIG. 13 is an enlarged cross-sectional view illustrating a layer structure of a stacked wafer according to a fourth exemplary embodiment.

FIG. 14 is an enlarged cross-sectional view illustrating a layer structure of a stacked wafer according to a modification of the fourth exemplary embodiment.

### DESCRIPTION OF THE EMBODIMENTS

Some exemplary embodiments of the present disclosure will now be described in detail with reference to the drawings. Dimensions, materials, shapes of components, and relative arrangement of the components described blow are appropriately changed depending on a configuration of an apparatus to which technical ideas of the present disclosure can be applied, and various kinds of conditions. In the following exemplary embodiments, an example in which the present disclosure is applied to manufacture of a semiconductor chip used for a liquid ejection head is described. However, the present disclosure is not used only in manufacture of a semiconductor chip for a liquid ejection head.

### <Liquid Ejection Apparatus>

### <Description of Liquid Ejection Apparatus>

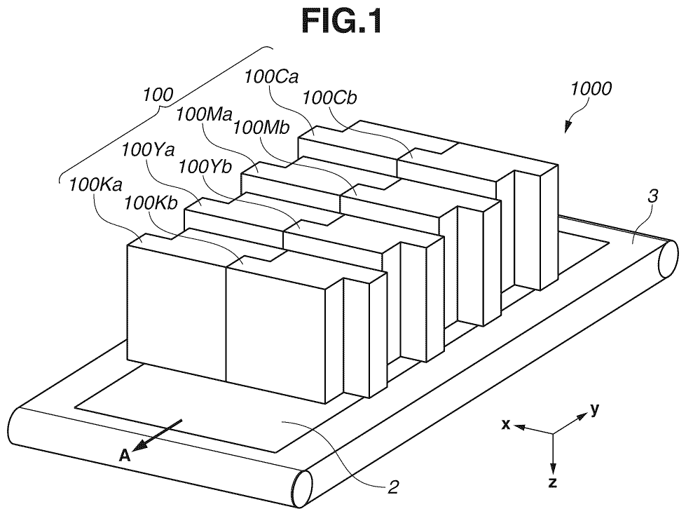

A first exemplary embodiment will be described. FIG. 1 is a schematic perspective view illustrating a schematic configuration of a liquid ejection apparatus 1000 according to an exemplary embodiment of a liquid ejection apparatus to which the present disclosure is applicable. The liquid ejection apparatus 1000 according to the present exemplary embodiment is a one-pass type that records an image on a recording medium 2 with a single movement of the recording medium 2, and ejection ports to eject liquid are arranged for the width of the recording medium 2. Liquid ejection heads 100 according to the present exemplary embodiment are, for example, detachably mounted on the liquid ejection apparatus 1000.

The recording medium 2 is conveyed by a conveyance unit 3 in the direction of an arrow A, and recording on the recording medium 2 is performed by the liquid ejection heads 100. The liquid ejection heads 100 are arranged on support members of liquid ejection units 10 each including an ejection chip 20 that can eject liquid (described below). The liquid ejection heads 100 are positioned in the liquid ejection apparatus 1000 by reference members. FIG. 1 illustrates the liquid ejection apparatus 1000 with two liquid ejection heads 100 for ejecting black ink, two liquid ejection heads 100 for ejecting yellow ink, two liquid ejection heads 100 for ejecting magenta ink, and two liquid ejection heads 100 for ejecting cyan ink, namely, eight liquid ejection heads 100 (100Ka, 100Kb, 100Ya, 100Yb, 100Ma, 100Mb, 100Ca, and 100Cb) in total mounted.

In the present specification, a direction parallel and opposite to the conveyance direction A of the recording medium 2 is referred to as a Y direction, a direction from the liquid ejection head 100 toward the recording medium 2 as a Z direction, and a direction perpendicular to both the Y direction and the Z direction, as well as to the conveyance direction A of the recording medium 2 as an X direction.

### <Description of Liquid Ejection Head>

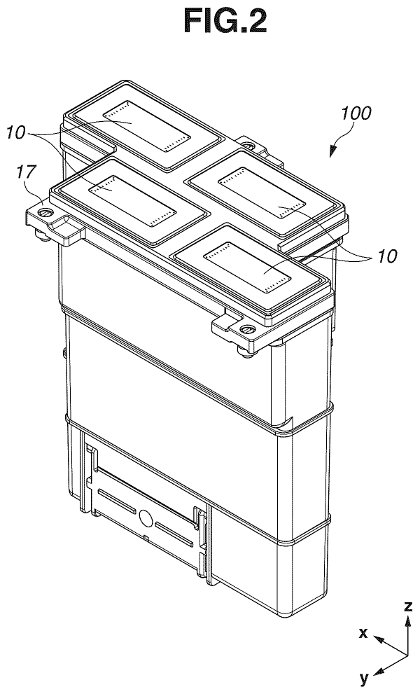

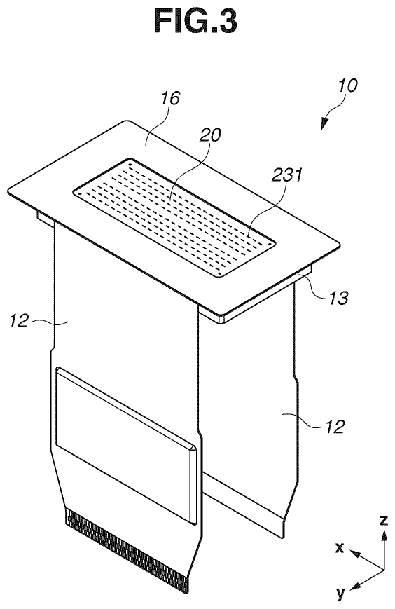

FIG. 2 is a perspective view of one liquid ejection head 100. FIG. 3 is a perspective view of one liquid ejection unit 10. In the liquid ejection head 100 according to the present exemplary embodiment, the plurality of liquid ejection heads 10 each including one of the ejection chips 20 with ejection ports for ejecting liquid is fixed onto a support member 17. The liquid ejection head 100 includes a cover member 16 on the surface of the ejection chip 20 opposite to the support member 17. Further, the liquid ejection head 100 includes a casing that houses electric substrates and other components. The liquid ejection head applicable to the present exemplary embodiment can be implemented in desired forms including the example illustrated in FIG. 2, but is not limited to those forms.

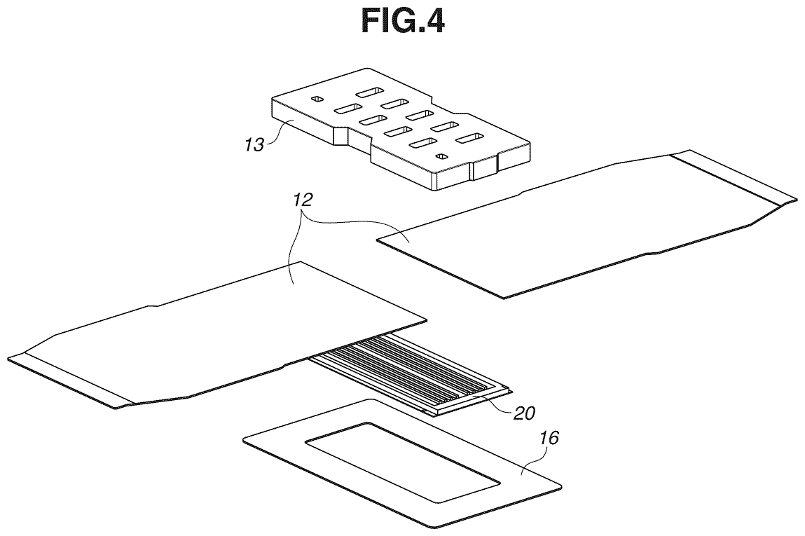

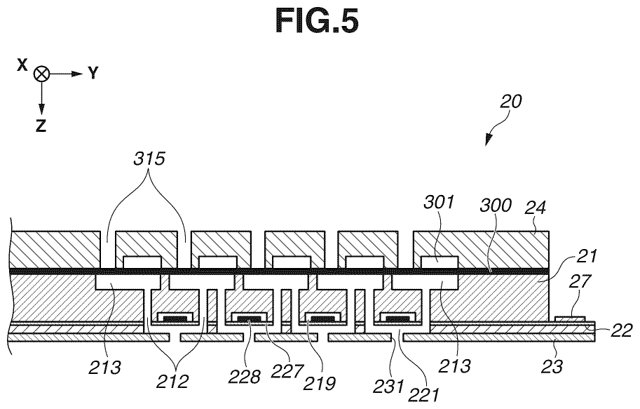

FIG. 4 is an exploded perspective view of one liquid ejection unit 10 as viewed from the surface of the ejection chip 20 opposite to the surface (the front surface) of the ejection chip 20 including ejection ports 231. The liquid ejection unit 10 includes the ejection chip 20, electric wiring members 12, and a flow path member 13. The ejection chip 20 includes the ejection ports 231 for ejecting the liquid, an actuator (see FIG. 5) for ejecting the liquid from the ejection ports 231, and terminals 27 (see FIG. 5) electrically connected to the actuator. The electric wiring members 12 are connected to the terminals 27 to supply the power for driving the actuator to pressure generation elements included in the actuator from the outside of the ejection chip 20. The flow path member 13 includes a flow path for supplying the liquid to the ejection ports 231, and is disposed adjacently to the ejection chip 20 on the rear surface opposite to the front surface of the ejection chip 20. The electric wiring members 12 are connected to the terminals 27 included in the ejection chip 20 on the rear surface of the ejection chip 20, and forms electric connection portions. In the present exemplary embodiment, the liquid ejection unit 10 further includes the cover member 16 for protecting the front surface of the ejection chip 20. In the present exemplary embodiment, as an example, alumina is used for the flow path member 13, and titanium is used for the cover member 16.

FIG. 5 is an enlarged cross-sectional view of a part of the ejection chip 20 of the liquid ejection head 100 according to the present exemplary embodiment. The ejection chip 20 includes four substrates that are an ejection port substrate 23, an actuator substrate 22, a flow path substrate 21, and a damper substrate 24. The ejection port substrate 23 includes the plurality of ejection ports 231. The plurality of ejection ports 231 is arranged in the X direction of the substrate to form an ejection port array and a plurality of ejection port arrays in the Y direction. The actuator substrate 22 includes pressure chambers 221, vibration plates 227, and pressure generation elements 228. The flow path substrate 21 includes individual flow paths 212, common flow paths 213, and grooves serving as gaps 219 surrounding the pressure generation elements 228. If the pressure generation elements 228 are piezoelectric elements, the gaps 219 are used in order to efficiently transfer deformations of the piezoelectric elements caused by voltage applications, to the vibration plates 227. The damper substrate 24 includes a damper film 300, damper chambers 301, and common openings 315. Ink is supplied from the common openings 315 in the damper substrate 24 to the ejection port substrate 23 through the flow path substrate 21 and the pressure chambers 221 of the actuator substrate 22, and the ink is ejected from the ejection ports 231 and applied to the recording medium 2. The liquid ejection head according to the present exemplary embodiment uses the piezoelectric elements as the pressure generation elements. However, the present exemplary embodiment can be suitably applied even to an ejection chip and a liquid ejection head using heating resistance elements as the pressure generation elements.

The ejection port substrate 23, the actuator substrate 22, and the flow path substrate 21 are silicon substrates in the present exemplary embodiment, and are hereinafter collectively referred to as a stacked chip 30. The stacked chip 30 includes the terminals 27 electrically connected to the electric wiring members 12. The electric connection of the terminals 27 and the electric wiring members 12 can be established by a desired connection method, such as wire bonding and non-conductive paste (NCP) bonding. The liquid ejection head according to the present exemplary embodiment can be implemented in various forms including the example illustrated in FIG. 2, but is not limited to those forms.

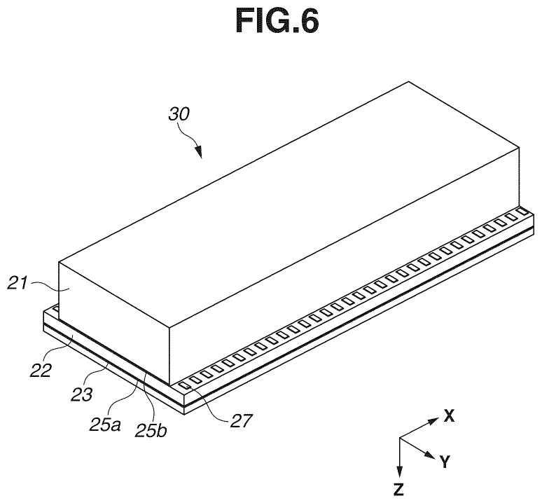

FIG. 6 is a schematic perspective view illustrating the stacked chip according to the present exemplary embodiment. FIG. 6 mainly illustrates a stacked configuration of the substrates, and an illustration of the flow paths included in the substrates is omitted. As illustrated in FIG. 6, in the present exemplary embodiment, the terminals 27 are arranged at end parts along sides of the ejection chip 20 (stacked chip 30). As a result, electric wires can be drawn from both end parts of the stacked chip 30. This makes it possible to increase the number of terminals 27 mountable on one ejection chip 20, which results in increase in the density of ejection port arrangement in the ejection chip 20. In the present exemplary embodiment, the terminals 27 are arranged in the two long sides of the ejection chip 20, and the electric wiring members 12 are connected thereto (also see FIGS. 3 and 4). Even if an ejection chip in which the terminals 27 are arranged in the short sides of the ejection chip 20 or the terminals 27 are arranged one side alone of the ejection chip 20, the present exemplary embodiment of the present disclosure can be suitably applied to those.

The flow path substrate 21 and the actuator substrate 22 are bonded with adhesive at a bonding interface 25b, and the actuator substrate 22 and the ejection port substrate 23 are bonded with adhesive at a bonding interface 25a.

### <Method for Manufacturing Ejection Chip>

In the present exemplary embodiment, the stacked chip 30 (the ejection port substrate 23, the actuator substrate 22, and the flow path substrate 21) of the ejection chip 20 can be manufactured by joining wafers as the respective substrates with adhesive, and then cutting the joined wafers by stealth dicing.

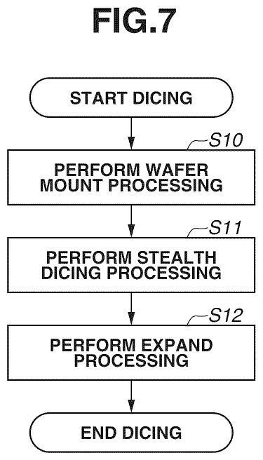

A stealth dicing method as a dicing method applicable to the present exemplary embodiment will be schematically described. FIG. 7 is a flowchart of the stealth dicing applicable to the present exemplary embodiment.

As illustrated in FIG. 7, in step S10, wafer mount processing for mounting a wafer is performed. More specifically, a dicing tape is attached to one surface of the wafer. The dicing tape is attached and fixed to a typical dicing frame greater than the outer periphery of the wafer, and then attached to the wafer. The surface of the wafer to which the dicing tape is attached may be either of the surfaces of the wafer. As the dicing tape, a tape is desirable that has adhesive force enough to hold the wafer in dicing and is easily removed from the wafer after cleavage. For example, in order to weaken the adhesive force after the dicing, a tape in which the adhesive is cured by ultraviolet (UV) irradiation can be used.

In step S11, stealth dicing processing, which involves irradiating the wafer with laser is performed. More specifically, laser irradiation is carried out along a predetermined dicing line set on the wafer. Further, a plurality of depth positions is irradiated with laser whose focal length varies, to form a plurality of modified regions in the wafer in a direction orthogonal to the surfaces of the wafer (a thickness direction of wafer). The laser beam may enter either of the surfaces of the wafer (the surface with a dicing tape attached thereto or the surface without a dicing tape). When the laser beam enters the surface with the dicing tape attached thereto, in consideration of laser beam attenuation by the dicing tape, it is desirable to appropriately adjust the laser output using a dicing tape with high laser permeability. When a deep position in the thickness direction of the wafer is irradiated with laser or a laser beam passes through a plurality of layers, absorption in and reflection from the wafer cause the laser beam to attenuate. Thus, a large amount of laser-beam attenuation in the wafer may prevent the laser irradiation from reaching the deepest portion in the thickness direction of the wafer from a single surface. In such a case, it is effective to irradiate both of the surfaces of the wafer with laser, specifically, for example, laser irradiation is switched from one surface to both of the surfaces of the wafer at a certain point in the thickness direction of the wafer.

In step S12, expand processing is performed to cleave the wafer. Expanding the dicing tape by predetermined force generates cracks in the modified regions as starting points, and the generated cracks are completely connected in the entire region in the thickness direction of the wafer to cleave the wafer. The expanding method is not particularly limited. For example, the wafer can be cleaved by expanding the dicing tape using an expander.

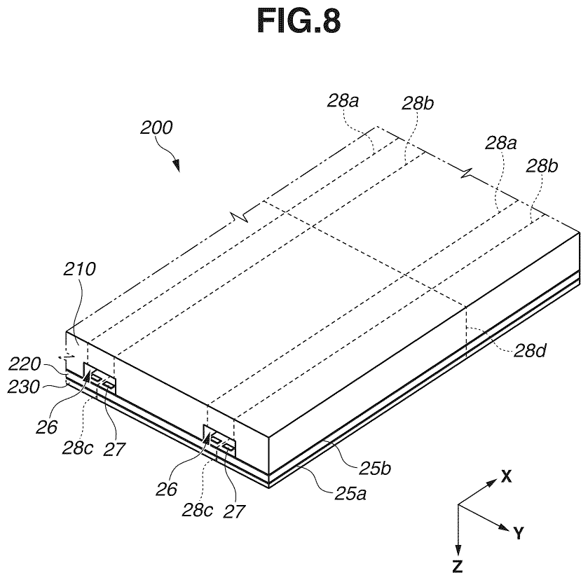

The following is a description of a method for manufacturing the stacked chip 30 as a semiconductor chip according to the first exemplary embodiment of the present disclosure. FIG. 8 is a schematic diagram illustrating a partial structure of a stacked wafer 200 before dicing. The stacked wafer 200 includes an ejection port wafer 230 to be the ejection port substrate 23, an actuator wafer 220 to be the actuator substrate 22, and a flow path wafer 210 to be the flow path substrate 21.

The flow path wafer 210 has a structure having recessed portions, and is joined to the actuator wafer 220 to cover the recessed portions, which results in hollow portions 26. The plurality of terminals 27 is provided in the hollow portions 26. Dicing lines (cutting lines) 28 (28a, 28b, 28c, and 28d) are laser irradiation lines for dividing the stacked wafer 200 into the stacked chips 30. In cutting processing of the stacked wafer 200, the stacked wafer 200 is irradiated with laser in a predetermined depth direction along the dicing lines 28. Rectangular parallelepiped regions surrounded by the dicing lines 28a and 28b of the flow path wafer 210 and the hollow portions 26 are portions removed after dicing. To surely remove the portions after cutting, the dicing lines 28a and 28b are arranged in a region of each of the hollow portions 26 as viewed from a direction perpendicular to a surface of the substrate.

In the present exemplary embodiment, the dicing tape is attached to the flow path wafer 210. Thus, the unnecessary portions of the flow path wafer 210 (the parallelepiped regions) are discarded while remaining on the dicing tape. The laser beams are applied to both a surface of the flow path wafer 210 and the surface on the ejection port wafer 230 with the hollow portions 26 serving as a boundary. The laser beam for the dicing lines 28a and 28b is applied to the flow path wafer 210, and the laser beam for the dicing line 28c is applied to the ejection port wafer 230. The laser beam is applied to one of the surfaces of the stacked wafer 200, the stacked wafer 200 is inverted, and then the laser beam is applied to the other surface of the stacked wafer 200. The surfaces may be cut in any order via the laser irradiation. The laser beams may be simultaneously applied to both the surfaces of the stacked wafer 200.

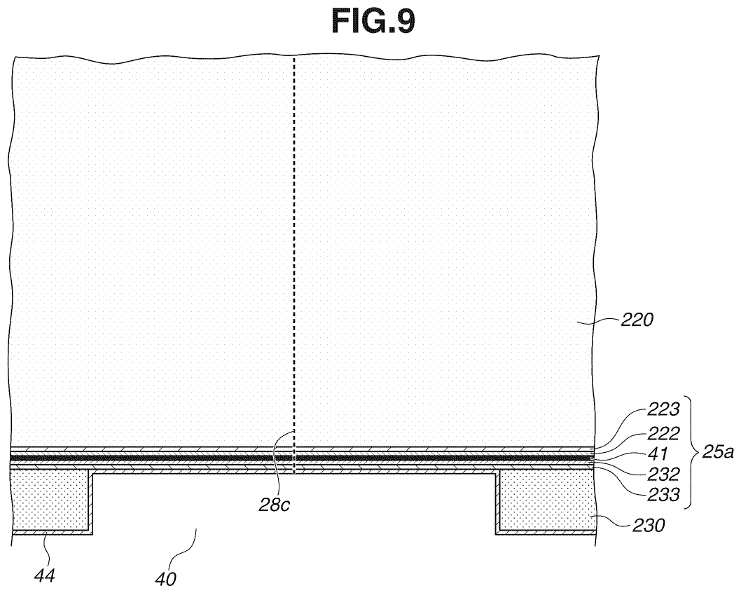

FIG. 9 is a schematic enlarged cross-sectional view of the bonding interface 25a between the actuator wafer 220 and the ejection port wafer 23 before dicing according to the present exemplary embodiment. In the following, cutting along the dicing line 28c at the bonding interface 25a between the actuator wafer 220 (a second wafer) and the ejection port wafer 230 (a first wafer) will be described in detail. In the stacked wafer 200, an adhesion improvement layer 222 for improving adhesiveness, and an insulating layer 223 are provided as intermediate layers between the bonding interface 25a and the actuator wafer 220. An adhesion improvement layer 232 and an insulating layer 233 are provided as intermediate layers between the bonding interface 25a and the ejection port wafer 230. The actuator wafer 220 and the ejection port wafer 230 are bonded via an adhesion layer 41.

Materials used for the insulating layer include a typical insulator material, such as silicon oxide, silicon nitride, silicon oxynitride, and aluminum oxide. The thickness of the insulating layer is desirably between 0.1 μm and 2.0 μm, and more desirably between 0.1 μm and 0.5 82 m. A material used for the adhesion improvement layer is appropriately selected based on the substrate and the material of adhesive.

In the present exemplary embodiment, the insulating layer 223 and the insulating layer 233 are each made of silicon monoxide (SiO), and the adhesion improvement layer 222 and the adhesion improvement layer 232 are each made of silicon carbide (SiC). In the present exemplary embodiment, an adhesive containing benzocyclobutene (BCB) is used for the adhesion layer 41.

In the stacked wafer 200 according to the present exemplary embodiment, a region 40 with the ejection port wafer 230 removed therefrom is provided along the dicing line 28c, centered on the dicing line 28c over a predetermined width. The width of the region 40 (a width in a direction orthogonal to the dicing line 28c) according to the present exemplary embodiment is 100 μm with the dicing line 28c serving as the center. The width of the region 40 is determined based on a laser irradiation depth and a laser incident width corresponding thereto, and is desirably greater than the sum of the incident width and a tolerance of the laser cutting position. Further, a protective layer 44 made of tantalum monoxide (TaO) for protecting the substrates from ink as an ejection liquid is provided on surfaces of the ejection port wafer 230 and the region 40.

The effect of provision of the above-described region 40 will be described in detail. At a laser focal point in stealth dicing, heat is generated during modification of the wafer. Thus, when the laser beam is applied to the stacked wafer 200 in the predetermined depth direction from the ejection port wafer along the dicing line 28c or 28d, the heat may be transferred to the bonding interface 25a. As a result, the actuator wafer 220 and the ejection port wafer 230 may be peeled at the bonding interface 25a due to stress derived from linear expansion difference between the plurality of layers at the bonding interface 25a. In particular, in order to satisfy ejection quality of the liquid ejection head, the ejection port wafer 230 according to the present exemplary embodiment has an extremely small thickness of 15 μm. Thus, when the laser beam is applied to the ejection port wafer 230 in order to modify the ejection port wafer 230, the possibility of the heat transfer to the bonding interface 25a increases, raising greater concern about wafer peeling. In a combination of the silicon wafer, SiO as the insulating layer, and SiC as the adhesion improvement layer according to the present exemplary embodiment, the linear expansion coefficient of silicon is 3.9×10⁻⁶/K, the linear expansion coefficient of SiO is 0.5×10⁻⁶/K to 0.65×10⁻⁶/K, and the linear expansion coefficient of SiC is 4.3×10⁻⁶/K to 4.5×10⁻⁶/K. The linear expansion coefficient difference between SiO as the insulating layer and the other joined layer is large. Thus, the linear expansion coefficient difference between the silicon wafer and the insulating layer, and the linear expansion coefficient difference between the insulating layer and the adhesion improvement layer are greater than the linear expansion coefficient difference between the silicon wafer and the adhesion improvement layer. In other words, the linear expansion coefficient difference between SiO as the insulating layer and the other joined layer is large, and stress caused by heat easily occurs in the insulating layer during laser irradiation. In the present exemplary embodiment, the region 40 is provided to prevent the laser beam from being applied to the ejection port wafer 230. On the ejection port wafer 230 irradiated with the laser beam, the interface where the ejection port wafer 230, the insulating layer 233, and the adhesion improvement layer 232 different in linear expansion coefficient from each other are joined to one another is removed along the dicing line 28c irradiated with the laser beam. This makes it possible to reduce stress derived from the linear expansion difference leading to wafer peeling. In addition, even when laser beam is applied to a vicinity of the bonding interface 25a of the actuator wafer 220, and laser thermal impact affects the bonding interface 25a, wafer peeling at the bonding interface 25a can be reduced since the ejection port wafer 230 does not exist at the laser irradiation position in the configuration according to the present exemplary embodiment.

In the dicing line 28d that intersects the dicing lines 28c and is provided for cutting the bonding interface 25a between the actuator wafer 220 and the ejection port wafer 230 of the stacked wafer 200, the region 40 where the ejection port wafer 230 is removed over a predetermined width with the dicing line 28d as the center is also provided as in FIG. 9.

As described above, in the present exemplary embodiment, the regions 40 with the ejection port wafer 230 removed therefrom are provided along the dicing lines 28c and the 28d, centered on the dicing lines 28c and 28d over their predetermined widths, respectively. This can reduce wafer peeling at the bonding interface 25a even when thermal impact during wafer modification by laser irradiation negatively affects the bonding interface 25a.

A second exemplary embodiment will now be described. Differences from the above-described first exemplary embodiment will mainly be described, and the description of a configuration similar to that according to the first exemplary embodiment is omitted.

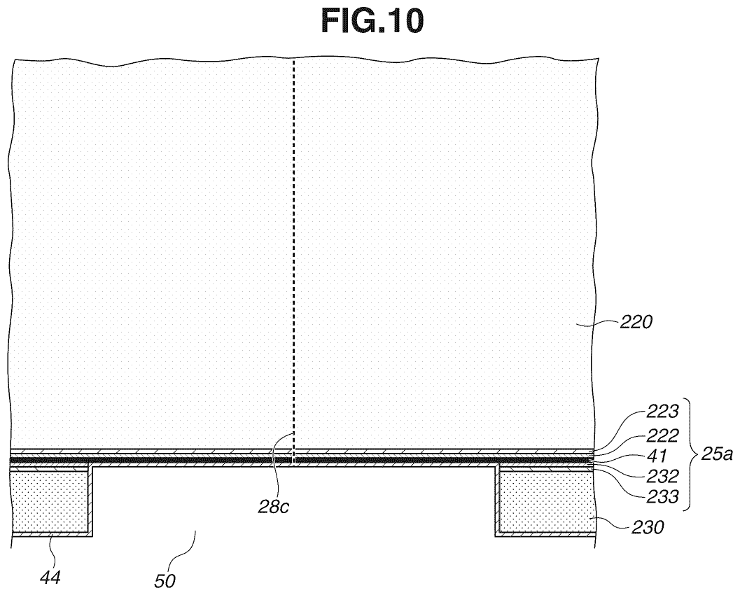

FIG. 10 is a schematic enlarged cross-sectional view of the bonding interface 25a between the actuator wafer 220 and the ejection port wafer 230 according to the present exemplary embodiment. As illustrated in FIG. 10, the present exemplary embodiment and the first exemplary embodiment are different in removed layers at the bonding interface 25a. In the present exemplary embodiment, a region 50 with the ejection port wafer 230, the insulating layer 233, and the adhesion improvement layer 232 removed therefrom is provided along the dicing line 28c, centered on the dicing line 28c over a predetermined width.

In the configuration according to the present exemplary embodiment, wafer peeling at the bonding interface 25a can be reduced since the ejection port wafer 230 does not exist as in the first exemplary embodiment. Furthermore, as compared with the case in the first exemplary embodiment, while removing processing of the adhesion improvement layer 232 and the insulating layer 223 is performed, attenuation influence during laser irradiation can be reduced because these layers do not exist at a laser irradiation position.

In the dicing line 28d intersecting the dicing line 28c, the region 50 having a predetermined width centered on the dicing line 28d is provided as in FIG. 10.

As described above, in the present exemplary embodiment, the regions 50 with the ejection port wafer 230, the insulating layer 233, and the adhesion improvement layer 233 removed therefrom are provided along the dicing lines 28c and 28d, centered on the dicing lines 28c and 28d over the predetermined widths, respectively. This can reduce wafer peeling at the bonding interface 25a even when thermal impact during wafer modification by laser irradiation negatively affects the bonding interface 25a.

A third exemplary embodiment will now be described. Differences from the above-described first exemplary embodiment will mainly be described, and the description of a configuration similar to that according to the first exemplary embodiment is omitted.

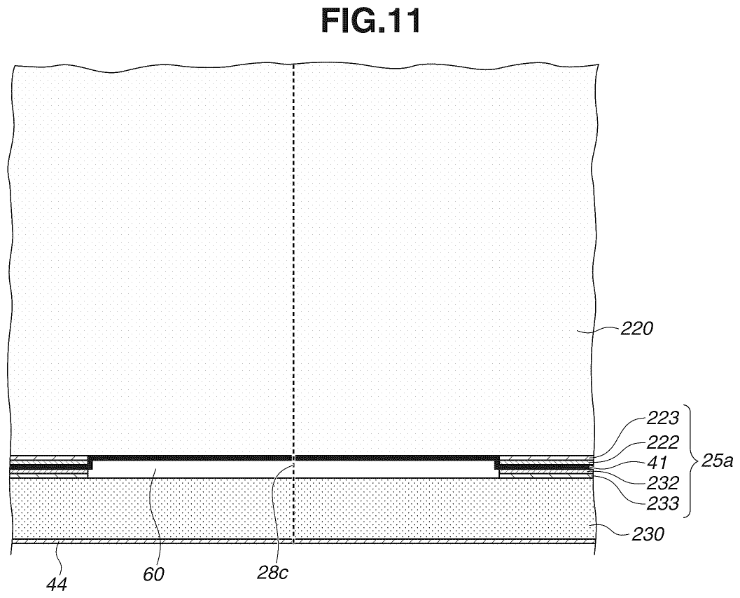

FIG. 11 is a schematic enlarged cross-sectional view of the bonding interface 25a between the actuator wafer 220 and the ejection port wafer 230 according to the present exemplary embodiment. As illustrated in FIG. 11, the present exemplary embodiment is different in removed layers at the bonding interface 25a from the first and second exemplary embodiments. In the present exemplary embodiment, a region 60 with a plurality of layers at the bonding interface 25a removed therefrom except for the adhesion layer 41 is provided along the dicing line 28c, centered on the dicing line 28c over a predetermined width. More specifically, the region 60 with the insulating layer 223 and the adhesion improvement layer 222 included in the actuator wafer 220, and the insulating layer 233 and the adhesion improvement layer 232 included in the ejection port layer 230 removed therefrom is provided along the dicing line 28c, centered on the dicing line 28c over the predetermined width. The region 60 is a space surrounded by the actuator wafer 220 and the ejection port wafer 230 while including the remaining adhesion layer 41 alone. In the configuration according to the present exemplary embodiment, an interface between a substrate and a layer largely different in linear expansion coefficient does not exist along the dicing line 28c irradiated with laser beam. This can reduce wafer peeling due to stress derived from linear expansion difference between the plurality of layers even when laser thermal impact affects the bonding interface 25a.

In FIG. 11, the adhesion layer 41 is present on the actuator wafer 220 side in the region 60, but the position of the adhesion layer 41 varies depending on which substrate the adhesion layer 41 is applied to. When the adhesion layer 41 is applied to the ejection port wafer 230, the adhesion layer 41 is present on the ejection port wafer 230 side in the region 60. The width of the region 60 according to the present exemplary embodiment is 100 μm with the dicing line 28c serving as the center.

In the present exemplary embodiment, as compared with the cases in the first and second exemplary embodiments, a space is present at the bonding interface 25a between the actuator wafer 220 and the ejection port wafer 230. Thus, laser attenuation may occur due to the transmission through the ejection port wafer 230 and its passage at an interface between the ejection port wafer 230 and the space, making the settings of the laser output for cleavage more complicated. On the other hand, it is sufficient to join wafers in which the layers (the insulating layer 223, the adhesion improvement layer 222, the adhesion improvement layer 232, and the insulating layer 233) provided on bonding surfaces are patterned, and it is unnecessary to remove the ejection port wafer 230 by etching.

In the dicing line 28d intersecting the dicing lines 28c, the region 60 having a predetermined width centered on the dicing line 28d is provided as in FIG. 11.

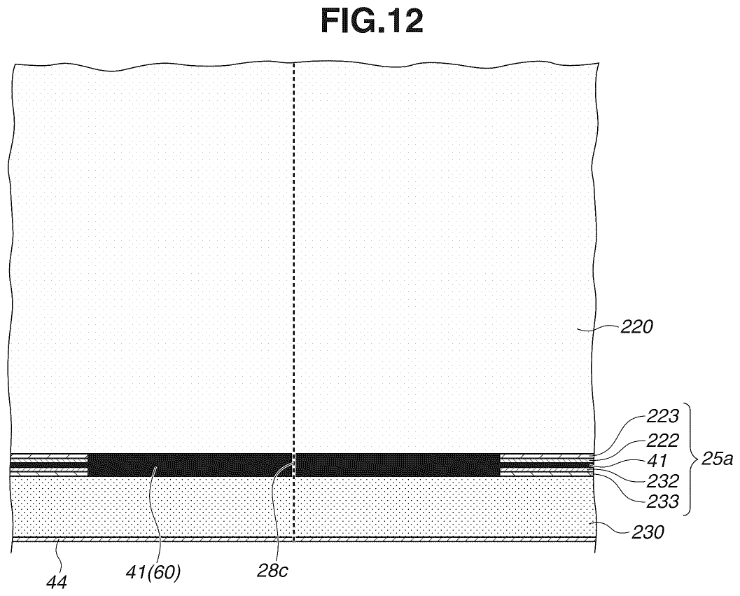

FIG. 12 illustrates a modification of the present exemplary embodiment. FIG. 12 is a schematic enlarged cross-sectional view of the bonding interface 25a between the actuator wafer 220 and the ejection port wafer 230 as in FIG. 11. A configuration illustrated in FIG. 12 is different from that illustrated in FIG. 11, and the region 60 is filled with the adhesion layer 41. Even in the configuration illustrated in FIG. 12, the layers other than the adhesion layer 41 does not exist at the bonding interface 25a in the laser irradiation position as in the configuration illustrated in FIG. 11. Thus, wafer peeling due to stress derived from linear expansion difference between the plurality of layers can be reduced.

As described above, in the present exemplary embodiment, the regions 60 with the plurality of layers constituting the bonding interface 25a removed therefrom except for the adhesion layer 41 are provided along the dicing lines 28c and 28d, centered on dicing lines 28c and 28d over the predetermined widths, respectively. This can reduce wafer peeling due to stress derived from linear expansion difference between the plurality of layers even when thermal impact during wafer modification by laser irradiation negatively affects the bonding interface 25a.

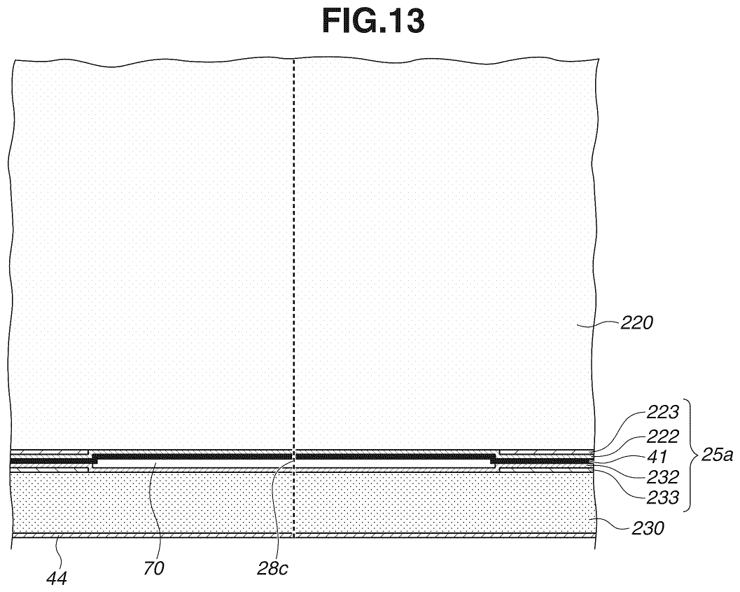

A fourth exemplary embodiment will now be described. In the following, differences from the above-described first and third exemplary embodiments will mainly be described, and the description of a configuration similar to that according to the first and third exemplary embodiments is omitted. FIG. 13 is a schematic enlarged cross-sectional view of the bonding interface 25a between the actuator wafer 220 and the ejection port wafer 230 according to the present exemplary embodiment. As illustrated in FIG. 13, the present exemplary embodiment and the third exemplary embodiment are different in removed layers at the bonding interface 25a. In the present exemplary embodiment, a region 70 where, among the plurality of layers at the bonding interface 25a, layers that can cause wafer peeling are removed are provided along the dicing lines 28c, centered on the dicing lines 28c over a predetermined width. More specifically, the layers that can cause wafer peeling are largely different in linear expansion coefficient from the other layers. In the present exemplary embodiment, the insulating layers 223 and 233 made of SiO are removed. As described above, at the bonding interface of the stacked wafer, at least one of the two joined layers having the largest linear expansion coefficient difference is removed, which makes it possible to reduce wafer peeling.

The configuration according to the present exemplary embodiment can reduce the number of layers to be patterned in the dicing lines 28c.

In the dicing line 28d intersecting the dicing lines 28c, the region 70 having a predetermined width, centered on the dicing line 28d is provided as in FIG. 13.

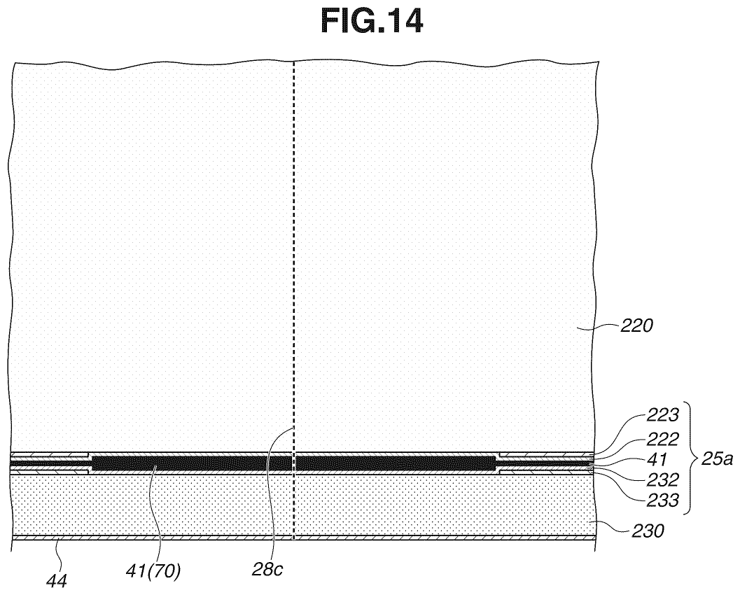

FIG. 14 illustrates a modification of the present exemplary embodiment. FIG. 14 is a schematic enlarged cross-sectional view of the bonding interface 25a between the actuator wafer 220 and the ejection port wafer 230 as in FIG. 13. A configuration illustrated in FIG. 14 is different from that illustrated in FIG. 13, and the region 70 is filled with the adhesion layer 41. Even in the configuration illustrated in FIG. 14, a bonding interface with a large difference in linear expansion coefficient, such as the interface between the actuator wafer 220 and the insulating layer 223 and the interface between the ejection port wafer 230 and the insulating layer 233, does not exist at the bonding interface 25a in the laser irradiation position as in the configuration illustrated in FIG. 13. This makes it possible to reduce wafer peeling due to stress derived from linear expansion difference.

As described above, in the present exemplary embodiment, the regions 70 with the plurality of layers at the bonding interface 25a removed therefrom except for the adhesion layer 41 are provided along the dicing lines 28c and 28d, centered on the dicing lines 28c and 28d over the predetermined widths, respectively. This can reduce wafer peeling due to stress derived from linear expansion difference between the adjacent layers even when thermal impact during wafer modification by laser irradiation affects the bonding interface 25a.

The exemplary embodiments provide a method for manufacturing a semiconductor chip and a method for dicing a stacked wafer that reduces peeling of a substrate at a bonding interface.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-060092, filed Apr. 3, 2024, which is hereby incorporated by reference herein in its entirety.

What is claimed is:

1. A method for manufacturing a plurality of semiconductor chips from a stacked wafer in which a first wafer and a second wafer are joined with adhesive, and at least one of the first wafer and the second wafer includes an intermediate layer provided on a side joined to the adhesive, the method comprising:
dicing the stacked wafer along a cutting line with cracks generated in a modified region formed by irradiation of laser beam from the first wafer,
wherein the dicing includes irradiating along a region where the first wafer is removed along the cutting line with a laser beam.

2. The method for manufacturing the semiconductor chips according to claim 1, wherein, in the dicing, the stacked wafer in which the intermediate layer is provided on the first wafer is cut.

3. The method for manufacturing the semiconductor chips according to claim 2, wherein, in the dicing, the stacked wafer including a region where the intermediate layer is removed as the region where the first wafer is removed is cut.

4. A method for manufacturing semiconductor chips from a stacked wafer in which a first wafer and a second wafer is joined with adhesive, and at least one of the first wafer and the second wafer includes an intermediate layer provided on a side joined to the adhesive, the method comprising:
dicing the stacked wafer along a cutting line with cracks generated in a modified region formed by irradiation of laser beam from the first wafer,
wherein the dicing includes irradiating along a region where the intermediate layer is removed along the cutting line with a laser beam.

5. The method for manufacturing the semiconductor chips according to claim 4, wherein, in the dicing, the stacked wafer in which the region where the intermediate layer is removed is filled with the adhesive is cut.

6. The method for manufacturing the semiconductor chips according to claim 4, wherein, before the dicing, the region where the intermediate layer is removed is formed, and then the first wafer and the second wafer are bonded with the adhesive.

7. The method for manufacturing the semiconductor chips according to claim 4, wherein the intermediate layer includes a first intermediate layer included in the first wafer and a second intermediate layer included in the second wafer, and
wherein, in the dicing, the stacked layer in which both the first intermediate layer and the second intermediate layer are removed in the region is cut.

8. The method for manufacturing the semiconductor chips according to claim 4,
wherein the intermediate layer includes a first adhesion improvement layer as a layer where the first wafer is in contact with the adhesive, a first insulating layer provided in contact with the first adhesion improvement layer, a second adhesion improvement layer as a layer where the second wafer is in contact with the adhesive, and a second insulating layer provided in contact with the second adhesion improvement layer, and
wherein, in the dicing, the stacked wafer in which the first insulating layer and the second insulating layer are removed in the region is cut.

9. The method for manufacturing the semiconductor chips according to claim 8, wherein, in the dicing, the stacked wafer in which a linear expansion coefficient difference between the first wafer and the first insulating layer is greater than a linear expansion coefficient difference between the first wafer and the first adhesion improvement layer is cut.

10. The method for manufacturing the semiconductor chips according to claim 1, wherein, in the dicing, the stacked wafer including the intermediate layer is cut, the intermediate layer including a first adhesion improvement layer as a layer where the first wafer is in contact with the adhesive, a first insulating layer provided in contact with the first adhesion improvement layer, a second adhesion improvement layer as a layer where the second wafer is in contact with the adhesive, and a second insulating layer provided in contact with the second adhesion improvement layer.

11. The method for manufacturing the semiconductor chips according to claim 10, wherein, in the dicing, the stacked wafer in which the first wafer is made of silicon and the first insulating layer is made of silicon monoxide (SiO) is cut.

12. The method for manufacturing the semiconductor chips according to claim 1,
wherein the intermediate layer includes a first adhesion improvement layer as a layer where the first wafer is in contact with the adhesive, a first insulating layer provided in contact with the first adhesion improvement layer, a second adhesion improvement layer as a layer where the second wafer is in contact with the adhesive, and a second insulating layer provided in contact with the second adhesion improvement layer, and
wherein, in the dicing, the stacked wafer in which the first insulating layer is removed in the region where the first wafer is removed is cut.

13. A method for manufacturing a liquid ejection head including a semiconductor chip in which a first substrate and a second substrate are joined with adhesive, and at least one of the first wafer and the second wafer includes an intermediate layer provided on a side joined to the adhesive, the method comprising:
dicing the stacked wafer along a cutting line with cracks generated in a modified region formed by irradiation of laser beam from the first wafer,
wherein the dicing includes irradiating along a region where the first wafer is removed along the cutting line with a laser beam.

14. The method for manufacturing the liquid ejection head according to claim 13, further comprising forming ejection ports for ejecting liquid in the first wafer.

15. The method for manufacturing the liquid ejection head according to claim 14, further comprising forming a pressure chamber for supplying the liquid to the ejection ports, and a pressure generation element for ejecting the liquid from the ejection ports in the second wafer.
